(19) United States
(12) Patent Application Publication
(10) Pub. No.: US 2008/0157137 A1
(43) Pub. Date: Jul. 3, 2008

(54) Image Sensor and Fabricating Method Thereof

(76) Inventor: EUN SANG CHO, Yongin-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/842,676

(22) Filed: Aug. 21, 2007

(30) Foreign Application Priority Data
Dec. 27, 2006 (KR) 10-2006-0135764

(51) Int. Cl. H01L 31/0232; H01L 21/02

(52) U.S. Cl. 257/292; 257/432; 438/69; 438/70; 257/E31.127; 257/E21.002

(57) ABSTRACT

An image sensor and a method of fabricating an image sensor are provided. The image sensor can include a color filter layer formed on a substrate and a microlens array on the color filter layer. The microlens array includes a first set of microlenses formed of a low temperature oxide layer and a second set of microlenses formed of a photoresist layer. The second set of microlenses can be formed between the first set of microlenses to provide a zero gap.

### CROSS-REFERENCE TO RELATED APPLICATION

The present application claims the benefit under 35 U.S.C. §119 of Korean Patent Application No. 10-2006-0135764, filed Dec. 27, 2006, which is hereby incorporated by reference in its entirety.

### BACKGROUND

Complementary metal oxide semiconductor (CMOS) image sensors often include microlenses formed on their uppermost layer. Light condensed by the microlenses passes through a color filter array layer and a planarization layer and is incident to a light-receiving portion, such as a photodiode. The light incident to the light-receiving portion is converted into an electrical signal, and the image sensor can display an image using the electrical signal. The focal length of the microlenses, the sizes and distribution of color filters, the thickness of the planarization layer, and the pitch size of the photodiode each need to be taken into account such that they are all in cooperation with one another. Many times, the focal length of the microlens varies a lot and is difficult to standardize. Currently, when a microlens is formed, a basic shape is first formed using a photoresist layer through defocus of a scanner. Next, a thermal reflow process is performed on the microlenses. Thus, using current methods, the shape of a microlens is difficult to reproduce.

### BRIEF SUMMARY

Embodiments of the present invention provide an image sensor and a fabricating method thereof that can improve sensitivity by securing reproducibility and forming a zero gap between adjacent microlenses.

An embodiment provides an image sensor including: a color filter layer formed on a semiconductor substrate; and a microlens array formed on the color filter layer, the microlens array including a first set of microlenses formed of a low temperature oxide layer and a second set of microlenses formed of a photoresist layer.

An embodiment provides a fabricating method of an image sensor, the method including: forming a low temperature oxide layer on a color filter layer; forming a first photoresist layer on the low temperature oxide layer; patterning the first photoresist layer to form sacrificial microlenses; etching the sacrificial microlenses and low temperature oxide layer to form a first set of microlenses formed of the low temperature oxide layer; patterning a second photoresist layer between the first set of microlenses; and forming a microlens array including the first set of microlenses and a second set of microlenses formed of the second photoresist layer through heat treatment.

### BRIEF DESCRIPTION OF THE DRAWINGS

FIGS. 1 to 4 are conceptual views for illustrating an image sensor fabricating method according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

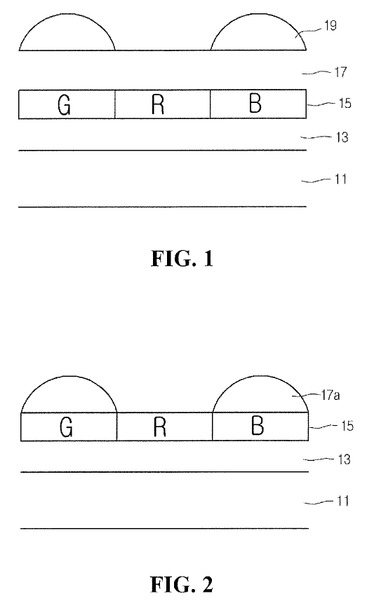

Referring to FIG. 1, in many embodiments of the present invention, a passivation layer 13 is formed on a lower structure 11, and a color filter layer 15 is formed on the passivation layer 13.

In many embodiments, the lower structure 11 includes a light-receiving portion and a wiring. In an embodiment, the light-receiving portion is a photodiode. The color filter layer 15 can include a red color filter, a green color filter, and a blue color filter, in any order. Also, in an embodiment, a thermosetting resin layer is formed under the color filter layer 15 before the color filter layer 15 is formed.

In many embodiments, a low temperature oxide (LTO) layer 17 is formed on the color filter layer 15. The LTO layer is used because the material of the color filter layer 15 may become damaged at increased temperatures, such as above 200° C.

In many embodiments, the LTO layer 17 is formed using a chemical vapor deposition (CVD) process. The LTO layer 17 can be formed of a material having greater hardness than that of a photoresist layer. In an embodiment, the LTO layer 17 is formed of a transparent material.

Subsequently, a photoresist layer can be formed on the LTO layer 17. A patterned photoresist layer is formed by performing exposure and development processes on the photoresist layer. Sacrificial microlenses 19 can be formed on a portion of the LTO layer 17 by performing heat treatment on the patterned photoresist layer.

Referring to FIG. 2, the sacrificial microlenses 19 and the LTO layer 17 are etched to form a first set of microlenses 17a formed of the LTO layer 17.

In certain embodiments, the etching of the sacrificial microlenses 19 and the LTO layer 17 is done by blanket etching using reactive ion etching (RIE).

In an embodiment, the etching of the sacrificial microlenses 19 and the LTO layer 17 is performed under a condition where a supply rate ratio is CHF₃:C₄F₈:Ar:O₂=5:2.5:50:1. In an embodiment, CHF₃ is supplied at a rate of about 15 standard cubic centimeters per minute (sccm) to about 25 sccm, C₄H₈ is supplied at a rate of about 5 sccm to about 15 sccm, Ar is supplied at a rate of about 180 sccm to about 220 sccm, and O₂ is supplied at a rate of about 3 sccm to about 5 sccm.

In an embodiment, the etching of the LTO layer 17 is performed under the following conditions:

| | |
|---|---|
| Pressure [mT] | 88 |
| Source POWER [W] | 300 |
| CHF₃ supply rate [sccm] | 20 |
| C₄F₈ supply rate [sccm] | 10 |
| Ar supply rate [sccm] | 200 |
| O₂ supply rate [sccm] | 4 |

In an embodiment of the present invention, etching selectivity between the sacrificial microlenses 19 and the LTO layer 17 is lowered, and the photoresist layer of the sacrificial microlenses 19 is consumed such that the shape of the sacrificial microlenses 19 is transferred to the LTO layer 17 to form the first set of microlenses 17a.

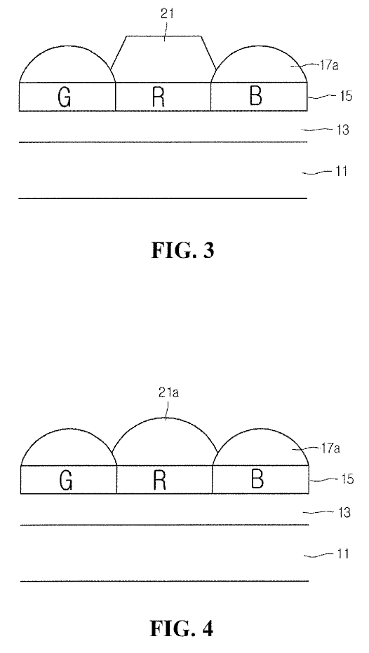

Referring to FIG. 3, a second photoresist layer 21 is patterned and formed between the first set of microlenses 17a.

Then, referring to FIG. 4, a second set of microlenses 21a formed of the second photoresist layer 21 is formed through heat treatment. Therefore, in many embodiments, a microlens array including the first set of microlenses 17a formed of the LTO layer and the second set of microlenses 21a formed of the photoresist layer can be formed. In certain embodiments, the first set of microlenses 17a and the second set of microlenses 21a are arranged in a checkerboard pattern.

In an embodiment, the pixel pitch of the second set of microlenses 21a is greater than the pixel pitch of the first set of microlenses 17a. In an embodiment, the pixel pitch of the second set of microlenses 21a is about 10% greater than the pixel pitch of the first set of microlenses 17a. In an alternative embodiment, the pixel pitch of the first set of microlenses 17a is greater than the pixel pitch of the second set of microlenses 21a. In an embodiment, the pixel pitch of the first set of microlenses 17a is about 10% greater than the pixel pitch of the second set of microlenses 21a.

In certain embodiments, the fact that heat treatment is performed with the pixel pitch of the second set of microlenses 21a being different than the pixel pitch of the first set of microlenses 17a allows a microlens to be formed such that no gap is present between adjacent microlenses. In an embodiment, the heat treatment performed is thermal reflow.

In an embodiment, the curvature radius of the second set of microlenses 21a is greater than the curvature radius of the first set of microlenses 17a.

In an embodiment, the second set of microlenses 21a have a greater curvature radius and are located on red color filters having relatively long wavelengths. In this embodiment, the first set of microlenses 17a have a smaller curvature radius and are located on green and blue color filters having relatively short wavelengths.

In embodiments where the first set of microlenses 17a are formed of a material having a greater hardness than that of a photoresist material, particles, such as polymers, are inhibited from being attached on the first set of microlenses 17a during a wafer back grinding or a sawing process. This leads to improved sensitivity and manufacturing yield of the image sensor, as well as reproducibility of the first set of microlenses 17a.

In an embodiment, a pad portion can be formed on the lower structure 11 and opened before the first set of microlenses 17a is formed. Since the photoresist layer can be formed on the open pad portion during a subsequent process, damage of the open pad portion can be inhibited.

In certain embodiments, after the first set of microlenses 17a and the second set of microlenses 21a have been formed, the passivation layer 13 can be etched to expose the pad portion formed on the lower structure 11. In an embodiment, a photoresist layer pattern is formed on the first set of microlenses 17a and the second set of microlenses 21a and etched to expose the pad portion.

In an embodiment, the pad portion can be exposed through a pad opening process. In an embodiment, a pad opening process is performed last, so that pad corrosion is minimized compared to when the pad is exposed before a final process.

In certain embodiments of the present invention, a planarization layer is formed on the color filter layer, and the first and second sets of microlenses are formed on the planarization layer.

In certain embodiments, an image sensor includes a lower structure 11 having a photodiode and a wiring, and a passivation layer 13 formed on the lower structure 11. The pad portion can be formed on the lower structure 11 to transmit a signal from the image sensor.

In many embodiments, the image sensor includes a color filter layer 15, a first set of microlenses 17a formed of an LTO layer and a second set of microlenses 21a formed of a photoresist layer on the color filter layer 15.

According to embodiments the image sensor includes a first set of microlenses 17a formed of a material having greater hardness than that of a photoresist material. This leads to inhibition of particles, such as polymers, being attached on the first set of microlenses 17a during a wafer back grinding or a sawing process.

According to an embodiment, the first set of microlenses 17a formed of the LTO layer and the second set of microlenses 21a formed of the photoresist layer are sequentially formed, leading to no gap between adjacent microlenses. Consequently, sensitivity and manufacturing yield of the image sensor can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a microlens array formed on a substrate, the microlens array comprising:
a first set of microlenses comprising a low temperature oxide;
a second set of microlenses comprising a photoresist; and
a color filter layer formed between the microlens array and the substrate.

2. The image sensor according to claim 1, wherein the first set of microlenses and the second set of microlenses are arranged in a checkerboard pattern.

3. The image sensor according to claim 1, wherein the color filter layer comprises red color filters, blue color filters, and green color filters; and
wherein the second set of microlenses is formed on the red color filters, and the first set of microlenses is formed on the blue color filters and the green color filters.

4. The image sensor according to claim 1, wherein the hardness of the low temperature oxide is greater than the hardness of the photoresist.

5. The image sensor according to claim 1, wherein the microlens array is formed such that no gap is present between adjacent microlenses.

6. The image sensor according to claim 1, wherein the second set of microlenses has a different pixel pitch than the first set of microlenses.

7. The image sensor according to claim 6, wherein the pixel pitch of the second set of microlenses is about 10% greater than the pixel pitch of the first set of microlenses.

8. The image sensor according to claim 6, wherein the pixel pitch of the first set of microlenses is about 10% greater than the pixel pitch of the second set of microlenses.

9. The image sensor according to claim 1, wherein the curvature radius of the second set of microlenses is greater than the curvature radius of the first set of microlenses.

10. A method of fabricating an image sensor, the method comprising:
forming a low temperature oxide layer on a substrate;
forming a first photoresist layer on the low temperature oxide layer;
patterning the first photoresist layer to form sacrificial microlenses;
etching the sacrificial microlenses and low temperature oxide layer to form a first set of microlenses formed of the low temperature oxide layer;
patterning a second photoresist layer on the substrate; and
forming a microlens array comprising the first set of microlenses and a second set of microlenses formed of the second photoresist layer through heat treatment.

11. The method according to claim 10, wherein etching the sacrificial microlenses and low temperature oxide layer to form a first set of microlenses formed of the low temperature oxide layer is performed before the patterning a second photoresist layer on the substrate.

12. The method according to claim 10, wherein the first set of microlenses and the second set of microlenses are arranged in a checkerboard pattern.

13. The method according to claim 10, wherein etching of the sacrificial microlenses and low temperature oxide layer comprises:
using CHF₃, C₄F₈, Ar, and O₂ with a supply rate ratio for CHF₃:C₄F₈:Ar:O₂ of about 5:2.5:50:1, wherein CHF₃ is supplied at a rate in the range of about 15 sccm to about 25 sccm, C₄H₈ is supplied at a rate in the range of about 5 sccm to about 15 sccm, Ar is supplied at a rate in the range of about 180 sccm to about 220 sccm, and O₂ is supplied at a rate in the range of about 3 sccm to about 5 sccm.

14. The method according to claim 10, wherein the microlens array is formed such that no gap is present between adjacent microlenses.

15. The method according to claim 10, wherein the second set of microlenses has a different pixel pitch than the first set of microlenses.

16. The method according to claim 15, wherein the pixel pitch of the second set of microlenses is about 10% greater than the pixel pitch of the first set of microlenses.

17. The method according to claim 15, wherein the pixel pitch of the first set of microlenses is about 10% greater than the pixel pitch of the second set of microlenses.

18. The method according to claim 10, further comprising forming a color filter layer on the substrate.

19. The method according to claim 18, wherein the color filter layer comprises red color filters, blue color filters, and green color filters; and
wherein the second set of microlenses is formed on the red color filters, and the first set of microlenses is formed on the blue color filters and the green color filters.
